(19) United States
(12) Patent Application Publication
(10) Pub. No.: US 2026/0038552 A1
(43) Pub. Date: Feb. 5, 2026

(54) UNIT CELL STRUCTURE FOR SPIN ORBIT TORQUE MAGNETORESISTIVE RANDOM ACCESS MEMORY

(71) Applicant: Micron Technology, Inc., Boise, ID (US)

(72) Inventors: Jun Yu, Singapore (SG); Bangxiu Li, Singapore (SG); Ying Jiang, Singapore (SG)

(21) Appl. No.: 18/789,059

(22) Filed: Jul. 30, 2024

(51) Int. Cl. G11C 11/16; H10B 61/00; H10N 50/10

(52) U.S. Cl. CPC G11C 11/161; G11C 11/1673; G11C 11/1675; H10B 61/22; H10N 50/10

(57) ABSTRACT

Systems, methods, and apparatus related to spin orbit torque magnetoresistive random access memory (SOT-MRAM) devices. In one approach, an SOT-MRAM device has a unit cell structure in which two or more magnetic tunnel junctions (MTJs) share a common spin orbit torque (SOT) layer. Bit data stored using each MTJ can be independently read and written. The unit cell structure permits using a higher bit storage density due to sharing of the SOT layer.

### FIELD OF THE TECHNOLOGY

At least some embodiments disclosed herein relate to memory devices in general, and more particularly, but not limited to spin orbit torque magnetoresistive random access memory (SOT-MRAM) devices.

### BACKGROUND

Magnetic random-access memory (MRAM) is a non-volatile computer memory technology based on magnetoresistance. One type of MRAM cell is a spin torque transfer MRAM (STT-MRAM) cell, which includes a magnetic cell core supported by a substrate. The magnetic cell core includes at least two magnetic regions, for example, a fixed region and a free region, with a non-magnetic region in between.

The fixed region includes a magnetic material that has a substantially fixed magnetic orientation (e.g., a non-switchable magnetic orientation during normal operation). The free region, on the other hand, includes a magnetic material that has a magnetic orientation that may be switched, during operation of the cell, between a parallel configuration and an anti-parallel configuration. In the parallel configuration, the magnetic orientations of the fixed region and the free region are directed in the same direction. In the anti-parallel configuration, the magnetic orientations of the fixed region and the free region are directed in opposite directions.

In the parallel configuration, the STT-MRAM cell exhibits a lower electrical resistance across the magnetoresistive elements (e.g., the fixed region and free region). This state of low electrical resistance may be defined as a “0” logic state of the STT-MRAM cell. In the anti-parallel configuration, the STT-MRAM cell exhibits a higher electrical resistance across the magnetoresistive elements. This state of high electrical resistance may be defined as a “1” logic state of the STT-MRAM cell.

Switching of the magnetic orientation of the free region may be accomplished by passing a programming current through the magnetic cell core and the fixed and free regions therein. The fixed region polarizes the electron spin of the programming current, and torque is created as the spin-polarized current passes through the core. The spin-polarized electron current exerts torque on the free region. When the torque of the spin-polarized electron current passing through the core is greater than a critical switching current density of the free region, the direction of the magnetic orientation of the free region is switched.

Thus, the programming current can be used to alter the electrical resistance across the magnetic regions. The resulting high or low electrical resistance states across the magnetoresistive elements enable the read and write operations of the STT-MRAM cell. After switching the magnetic orientation of the free region to achieve the parallel configuration or the anti-parallel configuration associated with a desired logic state, the magnetic orientation of the free region is usually desired to be maintained, during a storage stage, until the STT-MRAM cell is to be rewritten to a different logic state.

STT-MRAM can exhibit various technical limitations. The write current is high, which may lead to high energy consumption. In addition, the high current through the MTJ may cause severe stress for the memory cell. Also, the read and write operations share the same access path (through the junction), which may reduce reliability (e.g., read disturb). A read operation can mistakenly lead to a bit flip (magnetization of the storage layer is switched).

Spin orbit torque MRAM (SOT-MRAM) is an alternative in some cases. SOT-MRAM uses a three terminal MTJ-based concept to isolate the read and the write path compared to the two terminal approach of STT-MRAM. The read and write paths are perpendicular to each other, which improves read stability.

The storage device in spin orbit torque memories is a magnetic tunnel junction (MTJ) cell in which data is stored as a resistance state value. An MTJ device has two independent ferromagnetic layers separated by a thin barrier oxide layer. One of the two ferromagnetic layers has a fixed magnetization (the orientation of its magnetic field is fixed). This layer is known as a fixed or reference layer. In contrast, in the second magnetic layer, the magnetization can be freely rotated based on the current direction (spin of the electric particles) flowing through the MTJ device. This layer is referred to as a free layer.

When the direction of the magnetic field of the free layer is parallel (P) to the fixed layer (the magnetic field orientations in both layers are the same), the MTJ cell has a low resistance value. In contrast, when the magnetization of the free layer is opposite or anti-parallel (AP) to the fixed layer, the MTJ cell has a high resistance value. These high and low resistance values are used to represent logic ‘1’ and ‘0’ values.

### BRIEF DESCRIPTION OF THE DRAWINGS

The embodiments are illustrated by way of example and not limitation in the figures of the accompanying drawings in which like references indicate similar elements.

FIG. 1 shows a memory device that stores data for a host device, in accordance with some embodiments.

FIG. 2 shows an SOT-MRAM device that stores a single bit.

FIG. 3 shows a unit cell structure for an SOT-MRAM device that stores two bits, in accordance with some embodiments.

FIG. 4 shows a memory array formed by replicating the unit cell structure of FIG. 3, in accordance with some embodiments.

FIGS. 5-6 show biasing for writing first and second bits in an SOT-MRAM device, in accordance with some embodiments.

FIG. 7 shows biasing for reading first and second bits in an SOT-MRAM device, in accordance with some embodiments.

FIG. 8 shows a cross-sectional view of a two-bit SOT-MRAM device formed on a semiconductor substrate, in accordance with some embodiments.

FIG. 9 shows writing of an exemplary SOT-MRAM device having an MTJ formed on an SOT layer, in accordance with some embodiments.

FIG. 10 shows reading of the exemplary SOT-MRAM device of FIG. 9, in accordance with some embodiments.

FIG. 11 shows a free layer in the exemplary SOT-MRAM device of FIG. 9 that includes an optional synthetic antiferromagnet (SAF) structure, in accordance with some embodiments.

FIG. 12 shows a method for writing and reading an SOT-MRAM device, in accordance with some embodiments.

### DETAILED DESCRIPTION

The following disclosure describes various embodiments for memory devices that use spin orbit torque magnetoresistive random access memory (SOT-MRAM). The SOT-MRAM uses memory cells having a unit cell structure that stores two or more bits. Each of the memory cells has two or more magnetic tunnel junctions (MTJs) that share a common spin orbit torque (SOT) layer. By using this unit cell structure, the storage density of the SOT-MRAM is increased. The memory device may, for example, store data used by a host device (e.g., a computing device of an electric and/or autonomous vehicle, or another computing device that accesses data stored in the memory device).

Magnetic random-access memory (MRAM) includes two types of memory. One type of MRAM is spin torque transfer MRAM (STT-MRAM). Another type of MRAM is spin orbit torque MRAM (SOT-MRAM).

STT-MRAM is a two-terminal device with a one-transistor one-resistor (1T-1R) unit cell structure. SOT-MRAM is a three-terminal device with separate read and write routes. The SOT-MRAM device uses a two-transistor one-resistor unit cell structure (2T-1R).

During writing/programing of an SOT-MRAM memory cell, current does not go through the MTJ stack. This reduces the large current damage to the cell films that can occur with STT-MRAM. However, the three-terminal structure of SOT-MRAM requires using two transistors for read and write operations.

The use of two transistors for the 2T-1R structure of SOT-MRAM results in a larger unit cell area than for STT-MRAM. The larger unit cell area (e.g., causing lower storage density) required when using this 2T-1R structure is a significant limitation of SOT-MRAM and hinders its use in commercial products.

To address these and other technical problems, a spin orbit torque magnetoresistive random access memory (SOT-MRAM) is provided that uses a unit cell structure with two transistors driving two magnetic tunnel junctions (MTJs). This provides a two-transistor two-resistor (2T-2R) unit cell structure that is capable of storing two memory bits.

In various embodiments, each memory cell has a spin orbit torque (SOT) layer. Two or more magnetic tunnel junctions (MTJs) share the SOT layer. Each MTJ is configured to independently store a bit of data.

In one embodiment, two MTJs share a common SOT layer. An additional bit-line is added as compared to the 2T-1R structure of SOT-MRAM to enable the read and write control of each memory bit independently.

In one embodiment, the two transistors share a common source. This, for example, helps to reduce the effective unit area of CMOS that is required to drive the memory operations of the memory device, and the overall SOT-MRAM storage density can be further improved.

Various advantages are provided by at least some embodiments described herein. In one advantage, the device performance of prior MRAM is significantly improved, providing faster writing speed, longer endurance, improved device reliability, and non-volatile operation.

In one advantage, a memory device having memory cells in which MTJs share the SOT layer is a potential candidate to replace traditional memory (e.g., SRAM) used for an L1/L2 cache. This approach can provide comparable memory density to existing memory devices used for the L1/L2 cache.

In one advantage, the storage density can be effectively increased to approximately double the storage bits per unit area. This can reduce the cost per bit for manufacturing SOT-MRAM.

In one advantage, the use of two memory bits stored in a single unit structure, in which each bit can be read and written independently, provides random-access flexibility in using the memory.

In one advantage, a layout design method is provided that reduces the SOT-MRAM unit cell area (e.g., by about 40%). In some cases, this reduction in unit cell area can approximately reach the integration density of the 1T-1R unit cell structure of STT-MRAM. This can reduce or avoid the large cell area problem of the 2T-1R structure of SOT-MRAM. Also, by adding the additional bitline, each bit in the unit cell area can be operated independently.

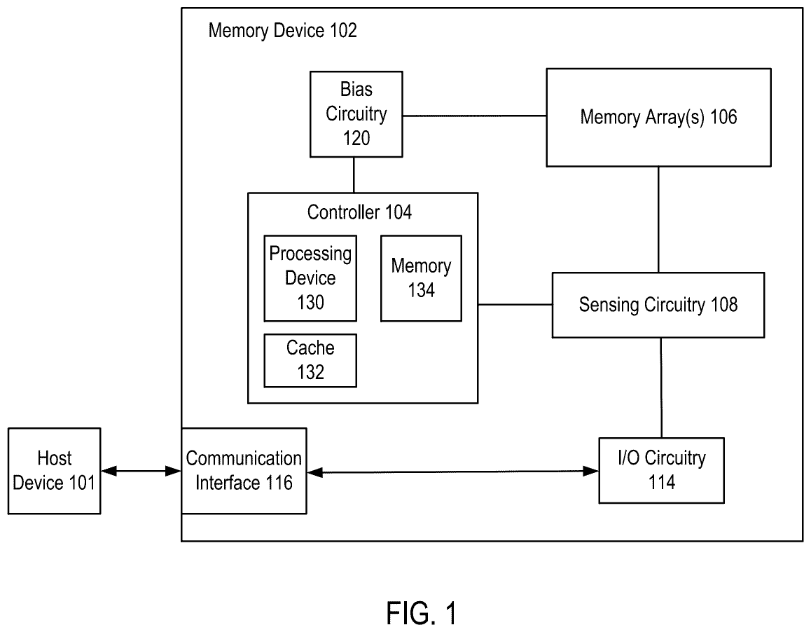

FIG. 1 shows a memory device 102 that stores data for a host device 101, in accordance with some embodiments. Memory device 102 has one or more memory arrays 106. Memory array 106 uses memory cells having a unit cell structure in which two or more MTJs share a common SOT layer.

In one embodiment, controller 104 services memory operations for data stored in memory array(s) 106. For example, write operations can be performed by controller 104 to address locations (e.g., for a source page) in memory array 106. In one example, read or write operations are performed in response to commands or other signals received from host device 101.

Controller 104 accesses portions of memory array(s) 106 in response to commands received from host device 101 via communication interface 116. Memory device 102 includes sensing circuitry 108. Sensing circuitry 108 (e.g., sense amplifiers) sense data stored in memory cells of memory arrays 106.

In one embodiment, each unit memory cell in memory array 106 has a spin orbit torque (SOT) layer. At least two magnetic tunnel junctions (MTJs) are formed overlying the SOT layer. Each of the MTJs has a free layer in contact with a top surface of the SOT layer. Sensing circuitry 108 is operated under control of controller 104 to read a state of each MTJ.

In one example, controller 104 accesses stored data by activating one or more rows of memory arrays 106. In one example, the activated rows correspond to a page of stored data.

Controller 104 uses bias circuitry 120 to apply voltages to various access lines (not shown) used to access memory cells in memory array 106. In one embodiment, the access lines include read and write wordlines, and first and second bitlines. In one embodiment, bias circuitry 120 applies voltages for programming and/or reading memory cells in array 106. In one example, the reading and/or programming voltage magnitudes and timings used are similar as those for an SOT-MRAM that implements a 2T-1R structure.

In one embodiment, controller 104 includes processing device 130, which accesses and/or stores data in memory 134. In one example, processing device 130 executes firmware stored in memory 134.

In one embodiment, controller 104 uses cache 132 for processing and/or other operations. In one embodiment, cache 132 is an L1/L2 cache using memory cells having two or more MTJs that share an SOT layer.

In one embodiment, memory device 102 is used as random access memory by host device 101. In one embodiment, memory device 102 is used as an L1/L2 cache by host device 101.

When a row of memory array 106 is activated, data can be read from the row as part of a read or other operation. Error correction circuitry (not shown) can be used to detect and correct any errors identified in the accessed data on the row for a read requested by host device 101. Corrected read data is provided for output on communication interface 116 by 1/O circuitry 114.

In one embodiment, communication interface (I/F) 116 is a bi-directional parallel or serial communication interface. The host device 101 can include a host processor (e.g., a host central processing unit (CPU) or other processor or processing circuitry, such as a memory management unit (MMU), interface circuitry, etc.).

In one embodiment, memory arrays 106 can be configured in a number of non-volatile memory devices (e.g., dies or LUNs), such as one or more stacked memory devices each including non-volatile memory (NVM) having one or more groups of non-volatile memory cells (e.g., SOT-MRAM) and a local device controller or other periphery circuitry thereon (e.g., device logic, etc.), and controlled by controller 104 over an internal storage-system communication interface (e.g., an Open NAND Flash Interface (ONFI) bus, etc.) separate from the communication interface 116.

In one embodiment, each memory cell in an MRAM architecture semiconductor memory array 106 can be programmed individually or collectively to one or a number of programmed states. A single-level cell (SLC) can represent one bit of data per cell in one of two programmed states (e.g., 1 or 0).

The controller 104 can receive instructions from the host device 101, and can transfer data to (e.g., write) or from (e.g., read) one or more of the memory cells of the memory arrays 106. The controller 104 can include, among other things, circuitry or firmware, such as a number of components or integrated circuits. For example, the controller 104 can include one or more memory control units, circuits, or components configured to control access across the memory array and to provide a translation layer between the host device 101 and a storage system, such as a memory manager, one or more memory management tables, etc.

In one embodiment, controller 104 can include circuitry or firmware, such as a number of components or integrated circuits associated with various memory management functions, including, among other functions, wear leveling, error detection or correction, bank or block retirement, or one or more other memory management functions.

In one embodiment, controller 104 can include a set of management tables (e.g., stored in memory 134) configured to maintain various information associated with one or more components of memory device 102 (e.g., various information associated with a memory array or one or more memory cells coupled to controller 104). For example, the management tables can include information regarding bank or block age, block erase count, error history, or one or more error counts (e.g., a write operation error count, a read bit error count, a read operation error count, etc.) for one or more banks or blocks of memory cells coupled to the controller 104.

In one embodiment, memory device 102 can include one or more three-dimensional architecture semiconductor memory arrays 106. The memory arrays 106 can include a number of memory cells arranged in, for example, banks, a number of devices, planes, blocks, physical pages, super blocks, or super pages.

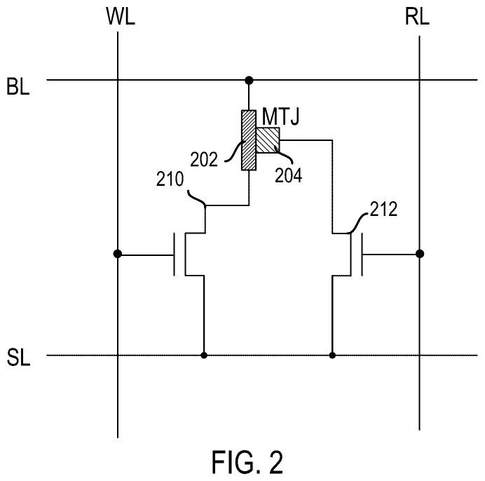

FIG. 2 shows an SOT-MRAM device that stores a single bit. The illustrated SOT-MRAM is a three-terminal device with separate read and write routes using read wordline RL and write wordline WL. SOT layer 202 is used to program the memory cell by changing a resistance of MTJ 204.

During writing/programming, current does not go through the memory cell films of MTJ 204. This reduces large current damage to the cell films. However, this three-terminal structure needs to use two transistors 210, 212 for read and write operations. Thus, the illustrated SOT-MRAM device has a 2T-1R structure, which makes the memory cell layout larger than an STT-MRAM having a 1T-1R structure.

In one embodiment, SOT layer 202 is used to write the memory. A controller switches on transistor 210 to inject current through SOT layer 202 to write data in the memory cell. The controller switches off transistor 212. This injecting of current will generate spin current that flips the state of a free layer (not shown) of MTJ 204. The free layer stores the desired information in the memory. The spin direction of the free layer is switched by this current injection.

For reading the memory cell, the controller switches off transistor 210, and switches on transistor 212. A relatively small current is injected to determine the resistance state of the memory cell. The resistance state corresponds, for example, to a logic 1 or 0.

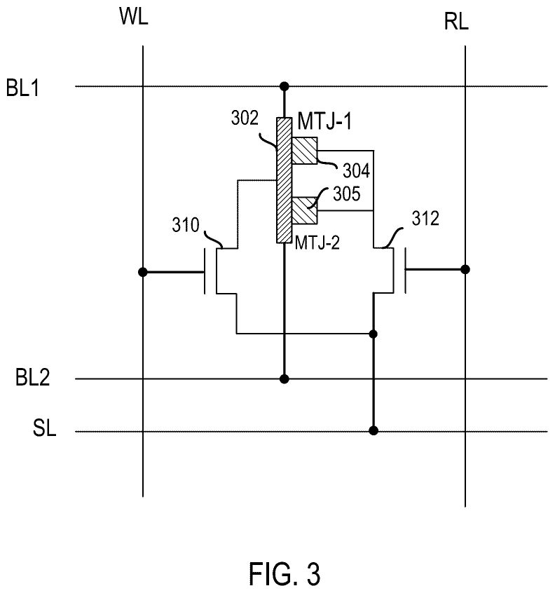

FIG. 3 shows a unit cell structure for an SOT-MRAM device that stores two bits, in accordance with some embodiments. The illustrated unit cell structure has two transistors 310, 312 driving two magnetic tunnel junctions (MTJs) 304, 305. This provides a two-transistor two-resistor (2T-2R) structure. This structure is capable of storing two memory bits. This permits storing data at a significantly higher density than for the 2T-1R structure of SOT-MRAM of FIG. 2. In one example, the illustrated unit cell structure is used for the layout of memory cells in memory array 106.

The two MTJs 304, 305 share a common SOT layer 302. Bitlines BL1, BL2 are used to enable read and write control of each memory bit independently. The two transistors 310, 312 have current terminals electrically connected to source line SL and share a common source. This, for example, helps to reduce the effective unit area of CMOS required to layout a memory array using the illustrated unit cell structure.

Transistor 310 is used to program each bit of the memory cell structure. A bias voltage is applied using write wordline WL to turn or switch on transistor 310. Bitlines BL1, BL2 are used to select one of two bits for programming. An electric current is injected through SOT layer 302 and flows under either of MTJ 304 or 305, depending on the biasing of bitlines BL1, BL2. For example, the current flows underneath MTJ 304 when programming bit 1 of the memory cell. The current flows underneath MTJ 305 when programming bit 2 of the memory cell. During programming, source line SL is connected to ground or a fixed voltage depending on the logic state being stored.

Transistor 312 is used to read each bit of memory cell structure. A bias voltage is applied using read wordline RL to turn or switch on transistor 312. A current is passed through either of MTJ 304 or 305 depending on the biasing of bitlines BL1, BL2. During reading, source line SL is connected to ground or a fixed voltage.

Sensing circuitry determines a state (e.g., logic 0 or 1) of the selected bit depending on the resistance of the corresponding MTJ. In one example, the sensing circuitry is sensing circuitry 108.

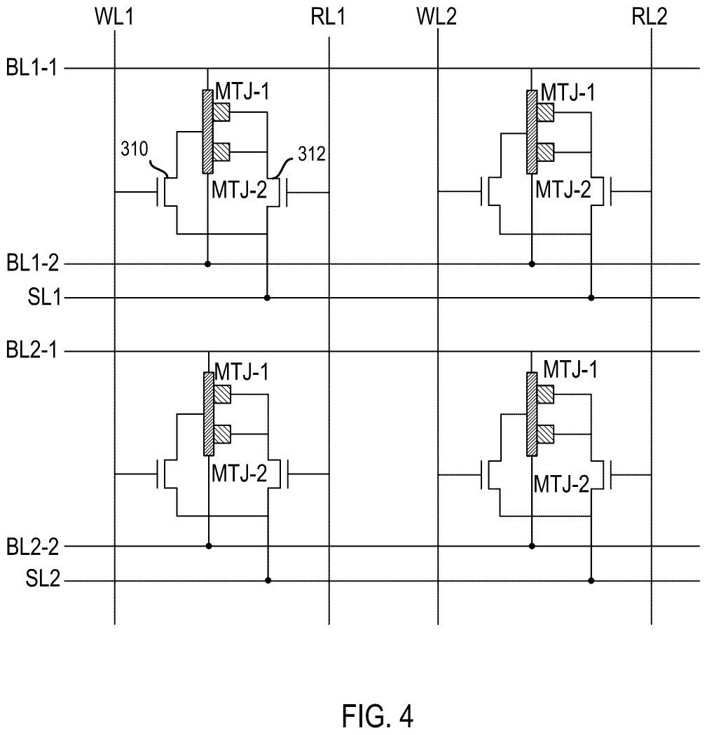

FIG. 4 shows a memory array formed by replicating the unit cell structure of FIG. 3, in accordance with some embodiments. In one example, the illustrated memory array is used to form memory array 106.

For programming, write wordline WL1 is biased to apply a voltage to a gate of several write transistors 310 in the memory array. For reading, read wordline RL1 is biased apply a voltage to a gate of several read transistors 312 in the memory array.

Write wordline WL2 and read wordline RL2 are used similarly.

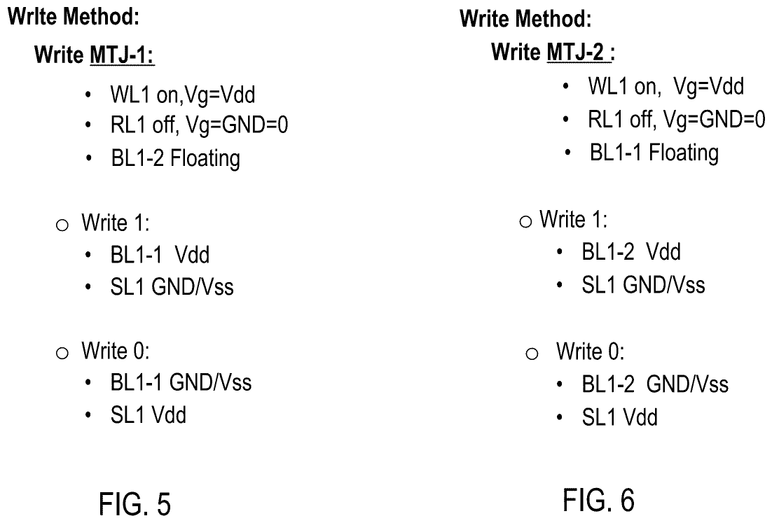

FIGS. 5-6 show biasing for writing first and second bits in an SOT-MRAM device, in accordance with some embodiments. The biasing of various access lines is illustrated using the access line and memory cell notation of FIG. 4. In one example, the access lines are biased using bias circuitry 120 under control of controller 104.

FIG. 5 illustrates programming or writing of a first bit MTJ-1. Voltages are applied to various access lines as illustrated for writing either of logic states 1 or 0. Write transistor 310 is turned on during programming. Read transistor 312 is turned off during programming.

In one example for writing the first bit, write wordline WL1 is turned on by applying a high voltage (e.g., Vdd) to the gate of write transistor 310. Read wordline RL1 is turned off by applying a low voltage (e.g., GND or 0 V) to the gate of read transistor 312. Bit line BL1-2 is left floating.

To write a logic state 1 to the first bit, bit line BL1-1 is held at a high voltage (e.g., Vdd). Source line SL1 is held at a low voltage (e.g., GND or Vss).

To write a logic state 0 to the first bit, bit line BL1-1 is held at a low voltage (e.g., GND or Vss). Source line SL1 is held at a high voltage (e.g., Vdd).

FIG. 6 illustrates voltages used for programming or writing of a second bit MTJ-2. Write transistor 310 is turned on during programming. Read transistor 312 is turned off during programming.

In one example, for writing the second bit, write wordline WL1 is turned on by applying a high voltage (e.g., Vdd) to the gate of write transistor 310. Read wordline RL1 is turned off by applying a low voltage (e.g., GND or 0 V) to the gate of read transistor 312. Bit line BL1-1 is left floating.

To write a logic state 1 to the second bit, bit line BL1-2 is held at a high voltage (e.g., Vdd). Source line SL1 is held at a low voltage (e.g., GND or Vss).

To write a logic state 0 to the second bit, bit line BL1-2 is held at a low voltage (e.g., GND or Vss). Source line SL1 is held at a high voltage (e.g., Vdd).

Other memory cells in the array can be written in a similar way.

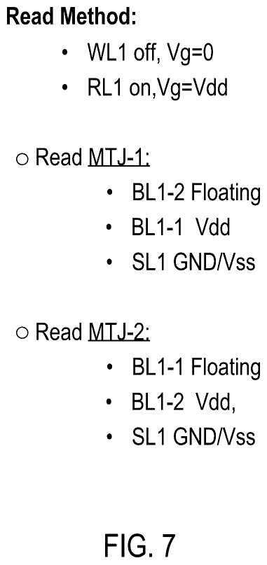

FIG. 7 shows biasing for reading first and second bits in an SOT-MRAM device, in accordance with some embodiments. The biasing of various access lines is illustrated using the access line and memory cell notation of FIG. 4. In one example, the access lines are biased using bias circuitry 120 under control of controller 104.

Write transistor 310 is turned off during reading. Read transistor 312 is turned on during reading. A resistance state of the MTJ corresponding to the stored bit is determined. The resistance state corresponds to a stored logic value.

In one embodiment, voltages applied to access lines during reading are significantly lower as compared to voltages used during writing.

In one example, for reading the first bit, write wordline WL1 is turned off by applying a low gate voltage (e.g., GND or 0 V) to write transistor 310. Read wordline RL1 is turned on by applying a high gate voltage (e.g., Vdd) to read transistor 312.

Bit line BL1-2 is left floating. Bit line BL1-1 is held at a high voltage (e.g., Vdd). Source line SL1 is held at a low voltage (e.g., GND or Vss).

In one example, for reading the second bit, write wordline WL1 is turned off by applying a low gate voltage (e.g., GND or 0 V) to write transistor 310. Read wordline RL1 is turned on by applying a high gate voltage (e.g., Vdd) to read transistor 312.

Bit line BL1-1 is left floating. Bit line BL1-2 is held at a high voltage (e.g., Vdd). Source line SL1 is held at a low voltage (e.g., GND or Vss).

Other memory cells in the array can be read in a similar way.

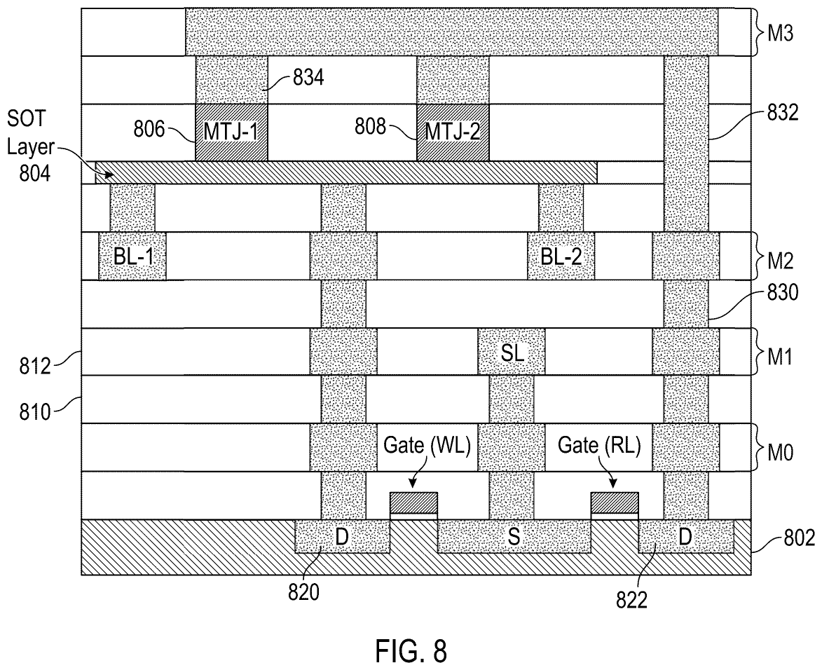

FIG. 8 shows a cross-sectional view of a two-bit SOT-MRAM device formed on a semiconductor substrate 802, in accordance with some embodiments. In one example, the illustrated device is based on the memory cell structure of FIG. 3.

Two MTJs 806, 808 are formed on a top surface of a common SOT layer 804.

Write transistor 820 and read transistor 822 are formed at a top surface of semiconductor substrate 802.

Various metal layers M0, M1, M2, M3 are used to provide circuit routing.

Metal layer M0 provides circuit routing for gates WL, RL. The metal layers M1, M2 provide circuit routing for source line SL, and bitlines BL-1, BL-2.

The various metal layers and the MTJs are electrically connected using various vertical interconnect 830, 832, 834 (e.g., vias). Various isolation layers 810, 812 provide electrical insulation between differing metal layers and circuit routing of the memory cell.

In one embodiment, additional bits of information can be stored in the memory cell structure by adding one or more additional MTJs that share SOT layer 804.

An additional bitline is added for each additional bit.

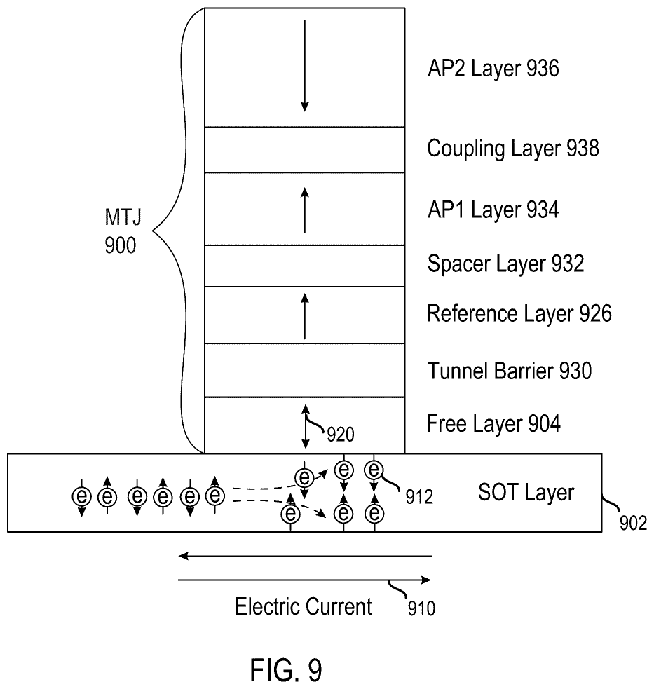

FIG. 9 shows writing of an exemplary SOT-MRAM device having an MTJ 900 formed on an SOT layer 902, in accordance with some embodiments. MTJ 900 is an example of MTJ 304, 305. SOT layer 902 is an example of SOT layer 302.

A bias is applied across SOT layer 902 to cause flow of an electric current 910. Electric current 910 causes a change in a spin direction 920 of free layer 904. The direction of the electric current 910 can be changed depending on the logic state being written. Reference layer 926 has a fixed spin direction that is not changed by electric current 910.

In one example, bias circuitry 120 is used to apply voltages to a bitline and a source line to cause electric current 910. The voltages applied determine the direction of current flow and the logic state that is written to the memory cell.

More specifically, electrons can have two spin orientations, spin up or spin down. When electric current 910 flows through SOT layer 902 from one end to the other, electrons 912 with opposite spin orientations flow to both sides of the SOT layer to form spin currents due to the spin-orbit coupling effect. The spin current then exerts torques and flips the spin orientations near the interface of free layer 904, providing the writing/programming operation of the device. Changing the electric current 910 flow direction flips the spin of the free layer 904 to the opposite orientation, thus writing/programming the device to a logic 1 or 0 state.

In one embodiment, the writing above can be performed in conjunction with programming techniques associated with spin transfer torque (STT) devices and/or use of an external magnetic field.

In one example, SOT layer 902 is formed using a heavy metal topological material. Electric current 910 is injected through the SOT layer. This causes spin orbit current due to characteristics of the material used to form the SOT layer. Spin orbit coupling with the electric current 910 causes generation of spin current. The spin current will flip the direction 920 of the free layer. The injected current can be caused to flow in either direction. This will result in different directions of spin current to flip the free layer.

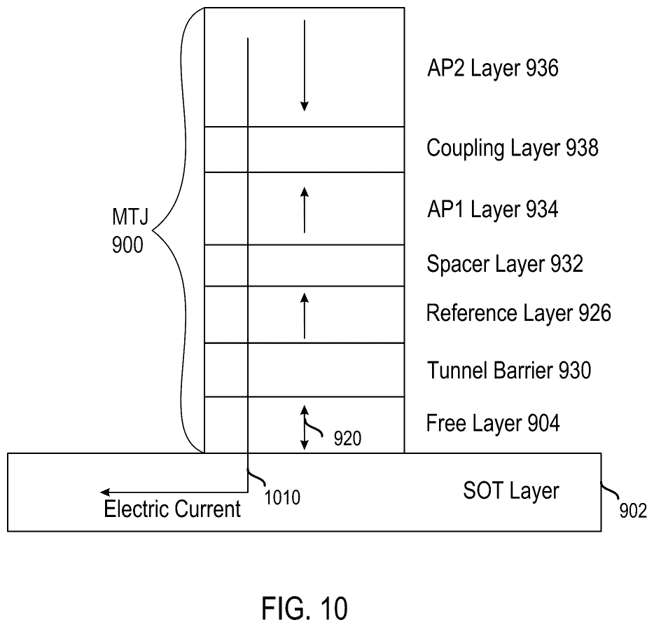

FIG. 10 shows reading of the exemplary SOT-MRAM device of FIG. 9, in accordance with some embodiments. Biasing of the device is done to cause electric current 1010 to flow through MTJ 900. The resistance of the device is determined by the relative spin orientations of reference layer 926 and free layer 904, as set during writing.

In one embodiment, similarly to STT-MRAM, the read operation of SOT-MRAM uses injection of a small amount of current through the MTJ stack. By reading the bitline BL current magnitude, the state of the MTJ (e.g., high-resistance state or low-resistance state (1 or 0)) can be detected.

In one example, an electric current 1010 tunnels through the MTJ 900 due to voltages applied by bias circuitry 120. When the reference layer 926 and the free layer 904 have the same directions of spin, the whole MTJ stack will exhibit a low resistance state. If the reference layer 926 and the free layer 904 have different directions of spin, the MTJ stack will exhibit a high resistance state. Only the spin of the free layer 904 is switched during programming. The reference layer 926 spin is fixed and acts as a standard to compare to the free layer 904 during reading.

In one non-limiting example, the structure of the SOT-MRAM device can be formed as follows. The SOT layer 902 can have a thickness of about 2-30 nm. The SOT layer 902 can have a material composition of heavy metals including Pt, Ta, or β-phase W. The material may also be a topological insulator (e.g., BiₓSe₁₋ₓ, or BiₓSb₁₋ₓ alloy).

Regarding the MTJ 900, the free layer 904 is the layer that stores information at the bottom of MTJ 900, in contact with the SOT layer 902. The thickness of the free layer 904 is, for example, about 0.8-1.3 nm, and the material composition can be CoFeB, FeB, or CoFe alloy.

The tunnel barrier 930 is typically MgO, having a thickness of about 0.8-1.3 nm. The tunnel barrier 930 can be made by magnetron sputtering of a MgO target or by using a thermal oxidation method. A heat treatment at 350-400° C. for 30 minutes to 1 hour can be used to change its crystal structure from amorphous to [100] crystal structure, which facilitates the spin current to tunnel through.

The reference layer 926 has a spin direction fixed in one direction, either spin up or down. If the spin of the free layer 904 is in the same direction, the MTJ 900 exhibits low resistance; if in the opposite direction, it exhibits high resistance. The thickness of the layer is, for example, about 0.8-1.3 nm, and the material composition can be CoFeB, FeB, or CoFe alloy.

The spacer layer 932 has, for example, a thickness of about 0.2-1.2 nm, and can be formed of a material such as Ta, or an alloy containing Co or Fe. W or Mo may also be included in the spacer layer to increase the thermal stability of the device.

The AP1 and AP2 layers 934, 936 provide antiferromagnetically coupling to each other. Each of the AP1 and AP2 layers 934, 936 may contain 4-20 bi-layers (not shown). The thickness of each AP1, AP2 layer can be 0.2-0.6 nm, and the material composition can be Co/Pt, Co/Pd, Co/Ni, etc.

The coupling layer 938 makes the AP1 and AP2 layers 934, 936 antiferromagnetically couple to each other. The thickness is, for example, about 0.4-0.9 nm, and the material can be Ru.

In one example, the spacer layer 932 is used because the reference layer 926 is fairly thin and can be easily degraded. The spacer layer 932 couples the spin of the reference layer 926 to the AP1 layer 934.

In one example, the spin of the AP1 and AP2 layers 934, 936 are coupled together. This makes the device structure more stable. Specifically, the AP1 and AP2 structure makes the magnetic spin stable. The AP1 and AP2 structure couples to the reference layer. The reference layer 926 and AP1 layer 934 have the same spin. Overall, the AP1 and AP2 structure is used to stabilize the spin in the reference layer. The coupling layer couples the magnetic directions of different spin directions.

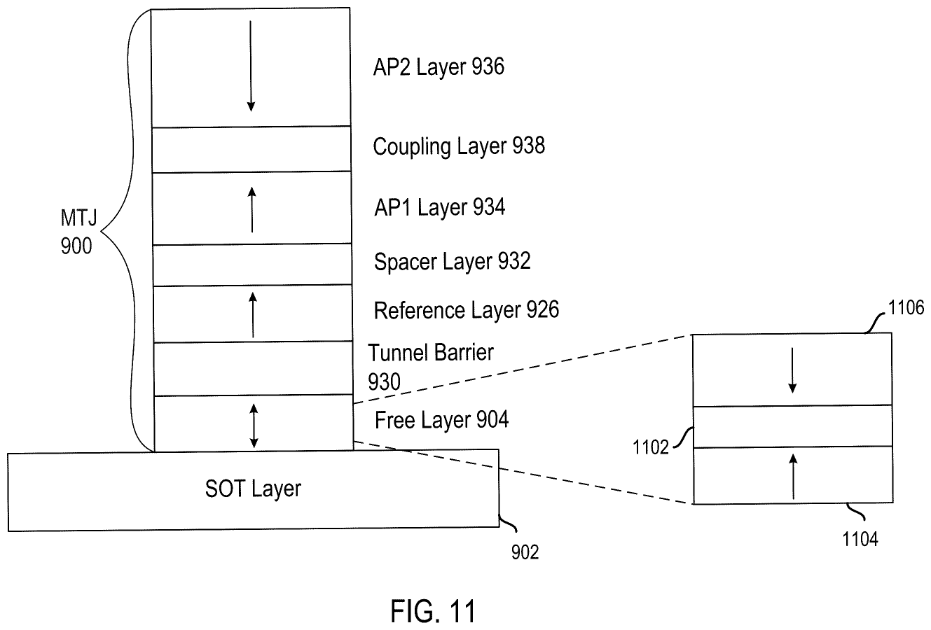

FIG. 11 shows a free layer 904 in the exemplary SOT-MRAM device of FIG. 9 that includes an optional synthetic antiferromagnet (SAF) structure, in accordance with some embodiments. The SAF structure includes AP2 layer 1106, AP1 layer 1104, and coupling layer 1102. The SAF structure can help to further stabilize the information stored in the memory cell and/or can avoid disturbance by external interference to the stored information.

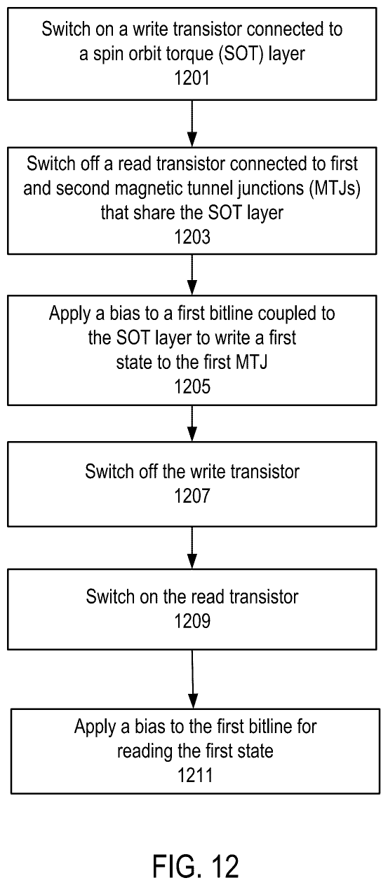

FIG. 12 shows a method for writing and reading an SOT-MRAM device, in accordance with some embodiments. For example, the method of FIG. 12 can be implemented in the system of FIG. 1.

The method of FIG. 12 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 12 is performed at least in part by one or more processing devices (e.g., controller 104 of FIG. 1).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 1201, a write transistor electrically connected to a spin orbit torque layer is switched on. In one example, bias circuitry 120 is used to switch on write transistor 310.

At block 1203, a read transistor connected to first and second magnetic tunnel junctions that share the SOT layer is switched off. In one example, the read transistor is read transistor 312.

At block 1205, a bias is applied to a first bitline coupled to the SOT layer. The bias is applied to write a first state (e.g., logic 0 or 1) to the first MTJ (e.g., MTJ-1). In one example, the bias is applied to bitline BL1, and the SOT layer is SOT layer 302.

At block 1207, the write transistor is switched off.

At block 1209, the read transistor is switched on. In one example, controller 104 switches off write transistor 310 and turns on read transistor 312.

At block 1211, a bias is applied to the first bitline for reading the first state. In one example, sensing circuitry 108 senses a state of a memory cell in memory array 106.

In some aspects, the techniques described herein relate to an apparatus including: a spin orbit torque (SOT) layer (e.g., 302, 804); and at least two magnetic tunnel junctions (MTJs) (e.g., 304, 305, 806, 808) configured to share the SOT layer.

In some aspects, the techniques described herein relate to an apparatus, wherein each MTJ is configured to independently store a bit of data.

In some aspects, the techniques described herein relate to an apparatus, wherein the MTJs include first and second MTJs, the apparatus further including: a first bitline configured for use in writing a first bit in the first MTJ; and a second bitline configured for use in writing a second bit in the second MTJ.

In some aspects, the techniques described herein relate to an apparatus, wherein the first bitline is electrically coupled to a source line (e.g., source line SL) by the SOT layer (e.g., 302) and a transistor (e.g., 310), and the second bitline is electrically coupled to the source line by the SOT layer and the transistor.

In some aspects, the techniques described herein relate to an apparatus, wherein three MTJs are configured to share the SOT layer.

In some aspects, the techniques described herein relate to an apparatus, further including a first transistor (e.g., 310) configured for independently writing each of first and second MTJs, and a second transistor (e.g., 312) configured for independently reading each of the first and second MTJs.

In some aspects, the techniques described herein relate to an apparatus, wherein the first and second transistors share a common source.

In some aspects, the techniques described herein relate to an apparatus, wherein the first transistor (e.g., 310) has a drain electrically connected to the SOT layer at a point between the first and second MTJs.

In some aspects, the techniques described herein relate to an apparatus, wherein the second transistor (e.g., 312) has a drain electrically connected to each of the first and second MTJs.

In some aspects, the techniques described herein relate to a method including: switching on, using a write wordline (e.g., voltage is Vdd), a first transistor having a current terminal connected to a spin orbit torque (SOT) layer; switching off, using a read wordline (e.g., voltage is GND), a second transistor having a current terminal connected to first and second magnetic tunnel junctions (MTJs) that share the SOT layer; and applying a bias to a first bitline coupled to the SOT layer, the bias determining a first state written to the first MTJ (e.g., bias of Vdd for logic 1, bias of Vss for logic 0).

In some aspects, the techniques described herein relate to a method, wherein a second bitline coupled to the SOT layer is floating while the first state is written to the first MTJ.

In some aspects, the techniques described herein relate to a method, wherein: the write wordline is coupled to a first gate of the first transistor; the read wordline is coupled to a second gate of the second transistor; bias circuitry (e.g., 120) is configured to bias the write wordline, the read wordline, and the first bitline.

In some aspects, the techniques described herein relate to a method, further including applying a bias to a second bitline coupled to the SOT layer, the bias determining a second state written to the second MTJ (e.g., bias of Vdd for logic 1, bias of Vss for logic 0), wherein the first bitline is floating while the second state is written to the second MTJ.

In some aspects, the techniques described herein relate to a method, further including: after the first state is written to the first MTJ, switching off, using the write wordline (e.g., voltage is GND), the first transistor; switching on, using the read wordline (e.g., voltage is Vdd), the second transistor; and applying a bias (e.g., Vdd) to the first bitline for reading the first state.

In some aspects, the techniques described herein relate to a method, wherein the first state is determined based on a resistance of the first MTJ.

In some aspects, the techniques described herein relate to a method, wherein a second bitline coupled to the SOT layer is floating while reading the first state.

In some aspects, the techniques described herein relate to an apparatus including: sensing circuitry (e.g., 108) configured in a semiconductor substrate (e.g., 802); a spin orbit torque (SOT) layer (e.g., 804) overlying the semiconductor substrate; and at least two magnetic tunnel junctions (MTJs) (e.g., 806, 808) overlying the SOT layer, wherein each MTJ has a free layer in contact with a top surface of the SOT layer; wherein the sensing circuitry is configured to read a state of each MTJ.

In some aspects, the techniques described herein relate to an apparatus, further including a metal layer (e.g., metal layer M2 of FIG. 8) underlying the SOT layer, wherein the metal layer includes a first bitline (e.g., BL-1) configured to read and write a first MTJ, and a second bitline (e.g., BL-2) configured to read and write a second MTJ.

In some aspects, the techniques described herein relate to an apparatus, further including: a write transistor (e.g., 820) configured in the semiconductor substrate, the write transistor having a drain electrically connected to the SOT layer by vertical interconnect; and a read transistor (e.g., 822) configured in the semiconductor substrate, the read transistor having a drain electrically connected to the MTJs by vertical interconnect (e.g., 830, 832, 834).

In some aspects, the techniques described herein relate to an apparatus, further including a source line (e.g., SL) patterned in a metal layer (e.g., metal layer M1 of FIG. 8) overlying the semiconductor substrate and underlying the SOT layer, wherein a source of the write transistor and a source of the read transistor are each connected to the source line.

The disclosure includes various devices which perform the methods and implement the systems described above, including data processing systems which perform these methods, and computer-readable media containing instructions which when executed on data processing systems cause the systems to perform these methods.

The description and drawings are illustrative and are not to be construed as limiting. Numerous specific details are described to provide a thorough understanding. However, in certain instances, well-known or conventional details are not described in order to avoid obscuring the description. References to one or an embodiment in the present disclosure are not necessarily references to the same embodiment; and, such references mean at least one.

As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

Reference in this specification to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

In this description, various functions and/or operations may be described as being performed by or caused by software code to simplify description. However, those skilled in the art will recognize what is meant by such expressions is that the functions and/or operations result from execution of the code by one or more processing devices, such as a microprocessor, Application-Specific Integrated Circuit (ASIC), graphics processor, and/or a Field-Programmable Gate Array (FPGA). Alternatively, or in combination, the functions and operations can be implemented using special purpose circuitry (e.g., logic circuitry), with or without software instructions. Embodiments can be implemented using hardwired circuitry without software instructions, or in combination with software instructions. Thus, the techniques are not limited to any specific combination of hardware circuitry and software, nor to any particular source for the instructions executed by a computing device.

While some embodiments can be implemented in fully functioning computers and computer systems, various embodiments are capable of being distributed as a computing product in a variety of forms and are capable of being applied regardless of the particular type of computer-readable medium used to actually effect the distribution.

At least some aspects disclosed can be embodied, at least in part, in software. That is, the techniques may be carried out in a computing device or other system in response to its processing device, such as a microprocessor, executing sequences of instructions contained in a memory, such as ROM, volatile RAM, non-volatile memory, cache or a remote storage device.

Routines executed to implement the embodiments may be implemented as part of an operating system, middleware, service delivery platform, SDK (Software Development Kit) component, web services, or other specific application, component, program, object, module or sequence of instructions (sometimes referred to as computer programs). Invocation interfaces to these routines can be exposed to a software development community as an API (Application Programming Interface). The computer programs typically comprise one or more instructions set at various times in various memory and storage devices in a computer, and that, when read and executed by one or more processors in a computer, cause the computer to perform operations necessary to execute elements involving the various aspects.

A computer-readable medium can be used to store software and data which when executed by a computing device causes the device to perform various methods. The executable software and data may be stored in various places including, for example, ROM, volatile RAM, non-volatile memory and/or cache. Portions of this software and/or data may be stored in any one of these storage devices. Further, the data and instructions can be obtained from centralized servers or peer to peer networks. Different portions of the data and instructions can be obtained from different centralized servers and/or peer to peer networks at different times and in different communication sessions or in a same communication session. The data and instructions can be obtained in entirety prior to the execution of the applications. Alternatively, portions of the data and instructions can be obtained dynamically, just in time, when needed for execution. Thus, it is not required that the data and instructions be on a computer-readable medium in entirety at a particular instance of time.

Examples of computer-readable media include, but are not limited to, recordable and non-recordable type media such as volatile and non-volatile memory devices, read only memory (ROM), random access memory (RAM), flash memory devices, solid-state drive storage media, removable disks, magnetic disk storage media, optical storage media (e.g., Compact Disk Read-Only Memory (CD ROMs), Digital Versatile Disks (DVDs), etc.), among others. The computer-readable media may store the instructions. Other examples of computer-readable media include, but are not limited to, non-volatile embedded devices using NOR flash or NAND flash architectures.

Media used in these architectures may include un-managed NAND devices and/or managed NAND devices, including, for example, eMMC, SD, CF, UFS, and SSD.

In general, a non-transitory computer-readable medium includes any mechanism that provides (e.g., stores) information in a form accessible by a computing device (e.g., a computer, mobile device, network device, personal digital assistant, manufacturing tool having a controller, any device with a set of one or more processors, etc.). A “computer-readable medium” as used herein may include a single medium or multiple media (e.g., that store one or more sets of instructions).

In various embodiments, hardwired circuitry may be used in combination with software and firmware instructions to implement the techniques. Thus, the techniques are neither limited to any specific combination of hardware circuitry and software nor to any particular source for the instructions executed by a computing device.

Various embodiments set forth herein can be implemented using a wide variety of different types of computing devices. As used herein, examples of a “computing device” include, but are not limited to, a server, a centralized computing platform, a system of multiple computing processors and/or components, a mobile device, a user terminal, a vehicle, a personal communications device, a wearable digital device, an electronic kiosk, a general purpose computer, an electronic document reader, a tablet, a laptop computer, a smartphone, a digital camera, a residential domestic appliance, a television, or a digital music player. Additional examples of computing devices include devices that are part of what is called “the internet of things” (IOT). Such “things” may have occasional interactions with their owners or administrators, who may monitor the things or modify settings on these things. In some cases, such owners or administrators play the role of users with respect to the “thing” devices. In some examples, the primary mobile device (e.g., an Apple iPhone) of a user may be an administrator server with respect to a paired “thing” device that is worn by the user (e.g., an Apple watch).

In some embodiments, the computing device can be a computer or host system, which is implemented, for example, as a desktop computer, laptop computer, network server, mobile device, or other computing device that includes a memory and a processing device. The host system can include or be coupled to a memory sub-system so that the host system can read data from or write data to the memory sub-system. The host system can be coupled to the memory sub-system via a physical host interface. In general, the host system can access multiple memory sub-systems via a same communication connection, multiple separate communication connections, and/or a combination of communication connections.

In some embodiments, the computing device is a system including one or more processing devices. Examples of the processing device can include a microcontroller, a central processing unit (CPU), special purpose logic circuitry (e.g., a field programmable gate array (FPGA), an application specific integrated circuit (ASIC), etc.), a system on a chip (SoC), or another suitable processor.

In one example, a computing device is a controller of a memory system. The controller includes a processing device and memory containing instructions executed by the processing device to control various operations of the memory system.

Although some of the drawings illustrate a number of operations in a particular order, operations which are not order dependent may be reordered and other operations may be combined or broken out. While some reordering or other groupings are specifically mentioned, others will be apparent to those of ordinary skill in the art and so do not present an exhaustive list of alternatives. Moreover, it should be recognized that the stages could be implemented in hardware, firmware, software or any combination thereof.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

In the foregoing specification, the disclosure has been described with reference to specific exemplary embodiments thereof. It will be evident that various modifications may be made thereto without departing from the broader spirit and scope as set forth in the following claims. The specification and drawings are, accordingly, to be regarded in an illustrative sense rather than a restrictive sense.

1. An apparatus comprising:
a spin orbit torque (SOT) layer; and
at least two magnetic tunnel junctions (MTJs) configured to share the SOT layer.

2. The apparatus of claim 1, wherein each MTJ is configured to independently store a bit of data.

3. The apparatus of claim 1, wherein the MTJs comprise first and second MTJs, the apparatus further comprising:
a first bitline configured for use in writing a first bit in the first MTJ; and
a second bitline configured for use in writing a second bit in the second MTJ.

4. The apparatus of claim 3, wherein the first bitline is electrically coupled to a source line by the SOT layer and a transistor, and the second bitline is electrically coupled to the source line by the SOT layer and the transistor.

5. The apparatus of claim 1, wherein three MTJs are configured to share the SOT layer.

6. The apparatus of claim 1, further comprising a first transistor configured for independently writing each of first and second MTJs, and a second transistor configured for independently reading each of the first and second MTJs.

7. The apparatus of claim 6, wherein the first and second transistors share a common source.

8. The apparatus of claim 6, wherein the first transistor has a drain electrically connected to the SOT layer at a point between the first and second MTJs.

9. The apparatus of claim 6, wherein the second transistor has a drain electrically connected to each of the first and second MTJs.

10. A method comprising:
switching on, using a write wordline, a first transistor having a current terminal connected to a spin orbit torque (SOT) layer;
switching off, using a read wordline, a second transistor having a current terminal connected to first and second magnetic tunnel junctions (MTJs) that share the SOT layer; and
applying a bias to a first bitline coupled to the SOT layer, the bias determining a first state written to the first MTJ.

11. The method of claim 10, wherein a second bitline coupled to the SOT layer is floating while the first state is written to the first MTJ.

12. The method of claim 10, wherein:
the write wordline is coupled to a first gate of the first transistor;
the read wordline is coupled to a second gate of the second transistor;
bias circuitry is configured to bias the write wordline, the read wordline, and the first bitline.

13. The method of claim 10, further comprising applying a bias to a second bitline coupled to the SOT layer, the bias determining a second state written to the second MTJ, wherein the first bitline is floating while the second state is written to the second MTJ.

14. The method of claim 10, further comprising:
after the first state is written to the first MTJ, switching off, using the write wordline, the first transistor;
switching on, using the read wordline, the second transistor; and
applying a bias to the first bitline for reading the first state.

15. The method of claim 14, wherein the first state is determined based on a resistance of the first MTJ.

16. The method of claim 14, wherein a second bitline coupled to the SOT layer is floating while reading the first state.

17. An apparatus comprising:
sensing circuitry configured in a semiconductor substrate;
a spin orbit torque (SOT) layer overlying the semiconductor substrate; and
at least two magnetic tunnel junctions (MTJs) overlying the SOT layer, wherein each MTJ has a free layer in contact with a top surface of the SOT layer;
wherein the sensing circuitry is configured to read a state of each MTJ.

18. The apparatus of claim 17, further comprising a metal layer underlying the SOT layer, wherein the metal layer comprises a first bitline configured to read and write a first MTJ, and a second bitline configured to read and write a second MTJ.

19. The apparatus of claim 17, further comprising:
a write transistor configured in the semiconductor substrate, the write transistor having a drain electrically connected to the SOT layer by vertical interconnect; and
a read transistor configured in the semiconductor substrate, the read transistor having a drain electrically connected to the MTJs by vertical interconnect.

20. The apparatus of claim 19, further comprising a source line patterned in a metal layer overlying the semiconductor substrate and underlying the SOT layer, wherein a source of the write transistor and a source of the read transistor are each connected to the source line.
